(19) United States
(12) Patent Application Publication
(10) Pub. No.: US 2012/0097184 A1
(43) Pub. Date: Apr. 26, 2012

(54) METHOD FOR RECYCLING WAFER

(76) Inventors: Ki Ho PARK, Hwaseong-si (KR); Kong Tan Sa, Suwon-si (KR); Suk Ho Yoon, Seoul (KR); Hyun Seok Ryu, Suwon-si (KR); Bo A Shin, Seoul (KR)

(21) Appl. No.: 13/275,099

(22) Filed: Oct. 17, 2011

(30) Foreign Application Priority Data
Oct. 20, 2010 (KR) 10-2010-0102217

(51) Int. Cl. H01L 21/02; B08B 5/00

(52) U.S. Cl. 134/3

(57) ABSTRACT

A method for recycling a wafer is provided. The method removes residues remaining on the wafer separated from a semiconductor layer, using HCl and Cl₂ gases under high temperature and low pressure conditions. According to the method, damage of a surface of the wafer is minimized. In addition, since reduction in thickness and an outer diameter of the wafer is minimized, a number of attempts at reprocessing the wafer may be increased.

### CROSS-REFERENCE TO RELATED APPLICATION

This application claims the benefit of Korean Patent Application No. 10-2010-0102217, filed on Oct. 20, 2010, in the Korean Intellectual Property Office, the disclosure of which is incorporated herein by reference.

### BACKGROUND

1. Field

Example embodiments of the following description relate to a method for recycling a wafer by removing residues remaining on the wafer.

2. Description of the Related Art

A semiconductor device is manufactured by forming a plurality of semiconductor layers on a wafer, and then performing processes including patterning, etching, polishing, and so forth. The wafer may be separated from the semiconductor layers for a separate use. Here, a physical, chemical, or thermal process may be used to separate the semiconductor layers vapor-deposited on the wafer, during which residues or byproducts may be produced on the wafer. Also, an upper surface of the wafer may be damaged.

Physical polishing is performed to remove the semiconductor layers from the overall surface of the wafer. Also, physical polishing and chemical etching are performed to remove residues from a lateral side and a rear side of the wafer. That is, since a damaged wafer needs to undergo physical and chemical etching and polishing to be recycled, thickness of the damaged wafer is reduced. Accordingly, a number of attempts at reprocessing the wafer is reduced.

Therefore, there is a need for a wafer recycling method, capable of removing residues remaining on the wafer, without damaging a surface of the wafer.

### SUMMARY

According to example embodiments, there may be provided a wafer recycling method capable of minimizing damage of an exterior surface of a wafer.

The foregoing and/or other aspects are achieved by providing a method for recycling a wafer, including removing residues remaining on a wafer, separated from a semiconductor m layer, using HCl and Cl₂ gases under high temperature and low pressure conditions, polishing the residue-removed wafer physically or chemically, and cleaning the polished wafer.

The removing of the residues may be performed at temperature from about 400° C. to about 2000° C., at a pressure from about 1 to about 10⁻⁹ torr.

The semiconductor layer may be a nitride semiconductor layer.

The nitride semiconductor layer may include any one selected from a group consisting of GaN, AlGaN, InGaN and AlInGaN.

The HCl and Cl₂ gases may separate GaN remaining on the wafer into GaCl and N.

The cleaning may be performed using a solution containing NH₄OH.

Additional aspects, features, and/or advantages of example embodiments will be set forth in part in the description which follows and, in part, will be apparent from the description, or may be learned by practice of the disclosure.

### BRIEF DESCRIPTION OF THE DRAWINGS

These and/or other aspects and advantages will become apparent and more readily appreciated from the following description of the example embodiments, taken in conjunction with the accompanying drawings of which:

FIG. 1 illustrates a flow chart showing a wafer recycling method according to example embodiments;

FIG. 2 illustrates a diagram showing a surface roughness of a new wafer for comparison with a surface roughness of a recycled wafer according to example embodiments; and

FIG. 3 illustrates a diagram showing a surface roughness of a recycled wafer according to example embodiments.

### DETAILED DESCRIPTION

Reference will now be made in detail to example embodiments, examples of which are illustrated in the accompanying drawings, wherein like reference numerals refer to the like elements throughout. Example embodiments are described below to explain the present disclosure by referring to the figures.

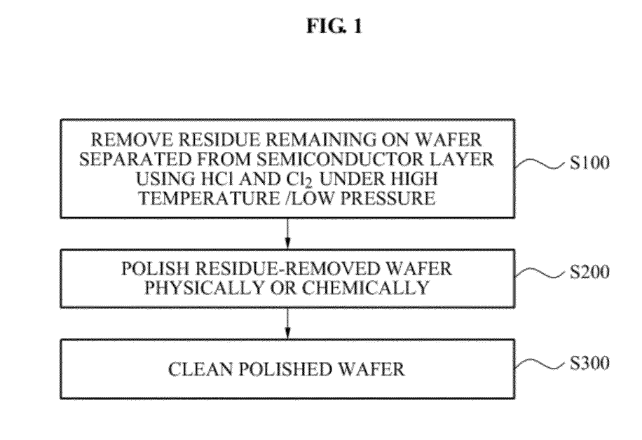

FIG. 1 illustrates a flow chart showing a wafer recycling method according to example embodiments.

Referring to FIG. 1, the wafer recycling method includes removing residues remaining on a wafer separated from a semiconductor layer, using HCl and Cl₂ gases under high temperature and low pressure conditions (S100), polishing the residue-removed wafer physically or chemically (S200), and cleaning the polished wafer (S300).

A semiconductor device is formed by depositing a plurality of semiconductor layers on the wafer. Here, the semiconductor layers may be separated from the wafer, such that the wafer may be reprocessed and reused. The example embodiments relate to a method for recycling a wafer used for manufacturing of the semiconductor device.

First, the residue remaining on the wafer is removed under high temperature and low pressure conditions, using the HCl and Cl₂ gases, in operation S100.

For example, the removing of the residue on the wafer may be performed at temperature from about 400° C. to about 2000° C., at a pressure from about 1 to about 10⁻⁹ torr.

The semiconductor layers may be nitride semiconductor layers containing GaN. For example, any one selected from a group consisting of GaN, AlGaN, InGaN and AlInGaN may used as the nitride semiconductor layer.

The semiconductor layers vapor-deposited on the wafer are subject to a stress caused by a lattice mismatch and a difference in thermal expansion coefficients between the wafer and the materials of the semiconductor layers. The stress induces a crack on a surface of the wafer during separation of the wafer from the semiconductor layers. Therefore, byproducts may remain on the wafer as residues. Polishing of the surface of the wafer is necessitated to remove the residues generated by the crack. However, the polishing reduces thickness of the wafer, thereby reducing a number of attempts at reprocessing the wafer.

However, the wafer recycling method, according to the example embodiments, removes residues on the wafer using an etching gas under high temperature and low pressure conditions. The etching gas may include HCl, Cl₂, and the like.

HCl and Cl₂ generate Cl⁻ ions under the high temperature and low pressure conditions. Alternatively, the Cl⁻ ions may be generated by plasma-processing the HCl and Cl₂. The Cl⁻ ions may separate the GaN into GaCl and N, the GaN which is the material of the nitride semiconductor layers remaining on the wafer. That is, the Cl⁻ ions may break a bond structure of the GaN.

In the case where the Cl⁻ ions remove the GaN residues, by breaking the bond structure of the GaN, that is the material of the semiconductor layers, residues and byproducts may be separated from the wafer, leaving a minimum damage to the surface of the wafer. Thus, the wafer recycling method, according to the example embodiments, may be able to remove the residues causing almost no damage to the surface of the wafer. Therefore, an outer diameter of the wafer may not change, and thickness reduction by reprocessing of the damaged wafer may be minimized to about 5 μm or less.

Next, the residue-removed wafer is polished physically or chemically, in operation S200. When the surface of the wafer is damaged, the damaged surface is polished for reuse of the wafer. The polishing process may planarize the surface where cracks are generated. In other words, since the damaged surface of the wafer becomes even, the wafer may be recycled. Methods of the polishing may include lapping, liquid honing, ultrasonic machining, barrel polishing, and the like.

However, when the surface of the residue-removed wafer is not damaged, that is, when the thickness and surface roughness of the residue-removed wafer are not changed compared to a new wafer, the polishing may be omitted.

Next, the polished wafer is cleaned in operation S300. The cleaning may be performed using a solution containing NH₄OH which is efficiently capable of removing organic contaminants. During the cleaning, any other residues and byproducts remaining on the wafer may be removed. For this purpose, besides the NH₄OH, various other solutions may be used according to types of the residues and byproducts. In addition, besides the solution cleaning method described above, various physical or chemical methods may be used to remove the residues and clean the wafer.

The wafer recycling method removes the residues remaining on the wafer, using HCl and Cl₂ gases under the high temperature and low pressure. Therefore, damage of the surface of the wafer may be minimized during the residue removal, while minimizing reduction in the thickness and the outer diameter of the wafer. As a result, the number of attempts at reprocessing the wafer may be increased.

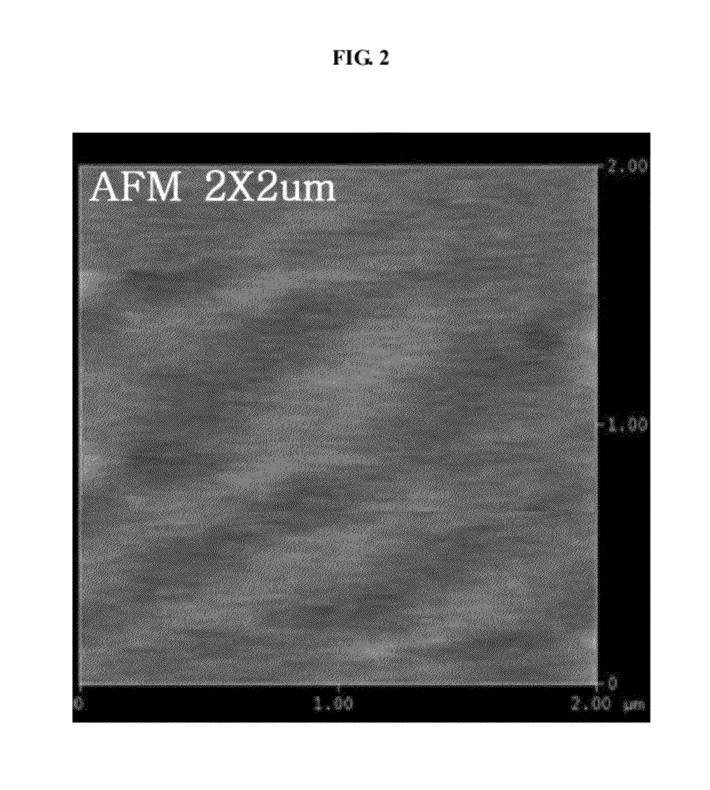

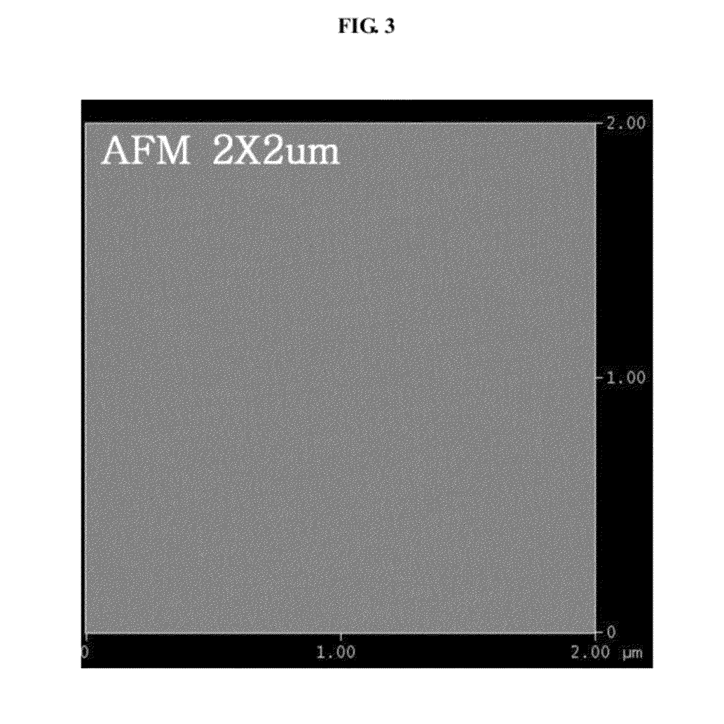

FIG. 2 illustrates a diagram a showing a surface roughness of a new wafer for comparison with a surface roughness of a recycled wafer according to example embodiments. FIG. 3 illustrates a diagram showing a surface roughness of a recycled wafer according to example embodiments.

Referring to FIGS. 2 and 3, the surface roughness of the recycled wafer according to the example embodiments is almost equal to the surface roughness of the new wafer.

The surface roughness may be expressed by a height difference between a highest peak and a lowest valley on a surface of a processing object. That is, as the height difference is greater, the surface roughness is higher.

In FIG. 2, the surface roughness of the new wafer is shown by a root mean square (RMS) of about 0.4 μm or less. In FIG. 3, the surface roughness of the recycled wafer is also m shown as an RMS of about 0.4 μm or less.

Thus, according to the recycled wafer of the example embodiments, reduction in the thickness and the outer diameter is minimized during removal of the residues remaining on the surface. Therefore, the number of attempts of reprocessing the wafer may be increased.

A wafer recycling method according to example embodiments removes residues remaining on a wafer separated from semiconductor layers, using HCl and Cl₂ gases under high temperature and low pressure conditions. Accordingly, damage of a surface of the wafer is minimized

Also, since reduction in thickness and an outer diameter of the wafer is minimized, a number of attempts at reprocessing the wafer may be increased.

Moreover, residues and byproducts on the wafer may be removed all at once.

Although example embodiments have been shown and described, it would be appreciated by those skilled in the art that changes may be made in these example embodiments without departing from the principles and spirit of the disclosure, the scope of which is defined in the claims and their equivalents.

What is claimed is:

1. A method for recycling a wafer, comprising:
removing residues remaining on a wafer separated from a semiconductor layer, using HCl and Cl₂ gases under high temperature and low pressure conditions;
polishing the residue-removed wafer physically and chemically; and
cleaning the polished wafer.

2. The method of claim 1, wherein the removing of the residues is performed at temperature from about 400° C. to about 2000° C., at a pressure from about 1 to about 10⁻⁹ torr.

3. The method of claim 1, wherein the semiconductor layer is a nitride semiconductor layer.

4. The method of claim 3, wherein the nitride semiconductor layer comprises any one selected from a group consisting of GaN, AlGaN, InGaN and AlInGaN.

5. The method of claim 4, wherein the HCl and Cl₂ gases separate GaN remaining on the wafer into GaCl and N.

6. The method of claim 1, wherein the cleaning is performed using a solution containing NH₄OH.
